(19) United States
(12) Patent Application Publication
(10) Pub. No.: US 2024/0413090 A1
(43) Pub. Date: Dec. 12, 2024

(54) SEMICONDUCTOR DEVICE

(71) Applicant: SUMITOMO ELECTRIC INDUSTRIES, LTD., Osaka (JP)

(72) Inventor: Toru HIYOSHI, Osaka (JP)

(21) Appl. No.: 18/701,757

(22) PCT Filed: Sep. 15, 2022
(86) PCT No.: PCT/JP2022/034554

§ 371 Date: Apr. 16, 2024

(30) Foreign Application Priority Data
Nov. 10, 2021 (JP) 2021-183513

(51) Int. Cl. H01L 23/538; H01L 23/00; H01L 25/07; H01L 29/36; H01L 29/78

(52) U.S. Cl. CPC H01L 23/5386; H01L 25/072; H01L 29/36; H01L 24/32; H01L 29/7813; H01L 2224/32225

(57) ABSTRACT

A semiconductor device includes an insulating substrate, a conductor pattern formed on the insulating substrate, and a plurality of semiconductor elements provided on the conductor pattern and electrically connected in parallel, wherein the conductor pattern has a minimum rectangular region surrounding the plurality of semiconductor elements in a plan view, each semiconductor element of the plurality of semiconductor elements has an epitaxial layer of a first conductivity type, the plurality of semiconductor elements include a first semiconductor element located nearest to a center of gravity of the rectangular region, and a second semiconductor element located farthest from the center of gravity of the rectangular region, and a first impurity concentration in the epitaxial layer of the first semiconductor element is higher than a second impurity concentration in the epitaxial layer of the second semiconductor element.

### TECHNICAL FIELD

The present disclosure relates to semiconductor devices.

This application is based upon and claims priority to Japanese Patent Application No. 2021-183513, filed on Nov. 10, 2021, the entire contents of which are incorporated herein by reference.

### BACKGROUND ART

Regarding a plurality of semiconductor elements connected in parallel on the same heat sink, a configuration is known in which intervals of the plurality of semiconductor elements is made larger at a center portion of the heat sink than at end portions of the heat sink, for the purpose of improving the heat dissipation of the semiconductor elements at the center portion of the heat sink (refer to Patent Document 1, for example).

### PRIOR ART DOCUMENTS

### Patent Documents

Patent Document 1: Japanese Laid-Open Patent Publication No. 2005-136229

### DISCLOSURE OF THE INVENTION

A semiconductor device according to present disclosure includes an insulating substrate, a conductor pattern formed on the insulating substrate, and a plurality of semiconductor elements provided on the conductor pattern and electrically connected in parallel, wherein the conductor pattern has a minimum rectangular region surrounding the plurality of semiconductor elements in a plan view, each of semiconductor element the plurality of semiconductor elements has an epitaxial layer of a first conductivity type, the plurality of semiconductor elements include a first semiconductor element located nearest to a center of gravity of the rectangular region, and a second semiconductor element located farthest from the center of gravity of the rectangular region, and a first impurity concentration in the epitaxial layer of the first semiconductor element is higher than a second impurity concentration in the epitaxial layer of the second semiconductor element.

### BRIEF DESCRIPTION OF THE DRAWINGS

FIG. 1 is a plan view illustrating a semiconductor device according to a first embodiment.

FIG. 2 is a cross sectional view illustrating the semiconductor device according to the first embodiment.

FIG. 3 is a diagram illustrating a unit cell of the semiconductor device.

FIG. 4 is a cross sectional view illustrating a semiconductor element.

FIG. 5 is a diagram illustrating a relationship between a temperature and a resistance of a transistor.

FIG. 6 is a graph illustrating breakdown characteristics of the transistor.

FIG. 7 is a graph illustrating the breakdown characteristics of the transistor.

FIG. 8 is a plan view illustrating the semiconductor device according to a second embodiment.

FIG. 9 is a cross sectional view illustrating the semiconductor device according to a modification of the second embodiment.

FIG. 10 is a cross sectional view illustrating the semiconductor device according to a third embodiment.

FIG. 11 is a cross sectional view illustrating the semiconductor device according to a modification of the third embodiment.

### MODE OF CARRYING OUT THE INVENTION

### Problem to be Solved by the Present Disclosure

In a conventional semiconductor device, the intervals of the plurality of semiconductor elements increase, to thereby increase the size of the semiconductor device.

One object of the present disclosure is to provide a semiconductor device capable of reducing variations in performance among a plurality of semiconductor elements without increasing the size.

### Effects of the Present Disclosure

According to the present disclosure, it is possible to reduce the variations in performance among the plurality of semiconductor elements without increasing the size.

Embodiments of the present disclosure will be described below.

### DESCRIPTION OF EMBODIMENTS OF THE PRESENT DISCLOSURE

First, the embodiments of the present disclosure will be described below. In the following description, the same or corresponding elements are designated by the same reference numerals, and the same description thereof will not be repeated. In a crystallographic description in the present specification and drawings, an individual orientation is represented by [ ], a group orientation is represented by < >, an individual plane is represented by ( ), and a group plane is represented by { }. In addition, a negative crystallographic index is generally represented by “-” (bar) above the numeral, but in the present specification, a negative sign is added before the numeral.

[1] A semiconductor device according to an aspect of the present disclosure includes an insulating substrate; a conductor pattern formed on the insulating substrate; and a plurality of semiconductor elements provided on the conductor pattern and electrically connected in parallel, wherein the conductor pattern has a minimum rectangular region surrounding the plurality of semiconductor elements in a plan view, each semiconductor element of the plurality of semiconductor elements has an epitaxial layer of a first conductivity type, the plurality of semiconductor elements include a first semiconductor element located nearest to a center of gravity of the rectangular region; and a second semiconductor element located farthest from the center of gravity of the rectangular region, and a first impurity concentration in the epitaxial layer of the first semiconductor element is higher than a second impurity concentration in the epitaxial layer of the second semiconductor element.

In this case, a resistance of the first semiconductor element becomes lower than a resistance of the second semiconductor element at room temperature, but a temperature rise of the first semiconductor element is greater than a temperature rise of the second semiconductor element during operation of the semiconductor device, and thus, a rising width of the resistance of the first semiconductor element becomes greater than the rising width of the resistance of the second semiconductor element. Accordingly, a difference between the resistances of the first semiconductor element and the second semiconductor element during the operation of the semiconductor device can be reduced.

In addition, at room temperature, a breakdown voltage of the first semiconductor element becomes lower than a breakdown voltage of the second semiconductor element, but the temperature rise of the first semiconductor element is greater than the temperature rise of the second semiconductor element during the operation of the semiconductor device, and thus, a rising width of the breakdown voltage of the first semiconductor element becomes greater than a rising width of the breakdown voltage of the second semiconductor element. Accordingly, it is possible to reduce variations in the breakdown voltage between the first semiconductor element and the second semiconductor element, and as a result, it is possible to reduce variations in an inductive load avalanche capability between the first semiconductor element and the second semiconductor element. Hence, variations in performance among the plurality of semiconductor elements can be reduced without increasing intervals of the semiconductor elements, that is, without increasing the size of the semiconductor device.

[2] In [1], the first impurity concentration may be highest among the plurality of semiconductor elements, and the second impurity concentration may be lowest among the plurality of semiconductor elements. In this case, the variations in the performance among the plurality of semiconductor elements can be particularly reduced.

[3] In [1] or [2], the plurality of semiconductor elements may include a third semiconductor element that is farther from the center of gravity of the rectangular region than the first semiconductor element is from the center of gravity of the rectangular region and nearer to the center of gravity of the rectangular region than the second semiconductor element is to the center of gravity of the rectangular region, and a third impurity concentration in the epitaxial layer of the third semiconductor element may be higher than the second impurity concentration and lower than the first impurity concentration. In this case, the variations in the performance among the plurality of semiconductor elements can be particularly reduced.

[4] A semiconductor device according to another aspect of the present disclosure includes an insulating substrate; a conductor pattern formed on the insulating substrate; and a plurality of semiconductor elements provided on the conductor pattern and electrically connected in parallel, wherein each semiconductor element of the plurality of semiconductor elements has an epitaxial layer of a first conductivity type, the plurality of semiconductor elements include a fourth semiconductor element having a largest number of semiconductor elements adjacent to each other; and a fifth semiconductor element having a smallest number of semiconductor elements adjacent to each other, and a fourth impurity concentration in the epitaxial layer of the fourth semiconductor element is higher than a fifth impurity concentration in the epitaxial layer of the fifth semiconductor element.

In this case, a resistance of the first semiconductor element becomes lower than a resistance of the second semiconductor element at room temperature, but a temperature rise of the first semiconductor element becomes greater than a temperature rise of the second semiconductor element during operation of the semiconductor device, and thus, a rising width of the resistance of the first semiconductor element becomes greater than a rising width of the resistance of the second semiconductor element. Accordingly, a difference between the resistances of the first semiconductor element and the second semiconductor element during the operation of the semiconductor device can be reduced.

In addition, at room temperature, a breakdown voltage of the first semiconductor element becomes lower than a breakdown voltage of the second semiconductor element, but the temperature rise of the first semiconductor element is greater than the temperature rise of the second semiconductor element during the operation of the semiconductor device, and thus, a rising width of the breakdown voltage of the first semiconductor element becomes greater than a rising width of the breakdown voltage of the second semiconductor element. Accordingly, it is possible to reduce variations in the breakdown voltage between the first semiconductor element and the second semiconductor element, and as a result, it is possible to reduce variations in an inductive load avalanche capability between the first semiconductor element and the second semiconductor element. Hence, variations in performance among the plurality of semiconductor elements can be reduced without increasing intervals of the semiconductor elements, that is, without increasing the size of the semiconductor device.

[5] In the [4], the fourth impurity concentration may be highest among the plurality of semiconductor elements, and the fifth impurity concentration may be lowest among the plurality of semiconductor elements. In this case, the variations in the performance among the plurality of semiconductor elements can be particularly reduced.

[6] In [4] or [5], the plurality of semiconductor elements may include a sixth semiconductor element having a number of adjacent semiconductor elements smaller than that of the fourth semiconductor element and larger than that of the fifth semiconductor element, and a sixth impurity concentration in the epitaxial layer of the sixth semiconductor element may be higher than the fifth impurity concentration and lower than the fourth impurity concentration. In this case, the variations in the performance among the plurality of semiconductor elements can be particularly reduced.

[7] A semiconductor device according to another aspect of the present disclosure includes an insulating substrate; a conductor pattern formed on the insulating substrate; and a plurality of semiconductor elements provided on the conductor pattern and electrically connected in parallel, wherein each semiconductor element of the plurality of semiconductor elements has an epitaxial layer of a first conductivity type, the plurality of semiconductor elements include a seventh semiconductor element having a highest temperature during operation; and an eighth semiconductor element having a lowest temperature during operation, and a seventh impurity concentration in the epitaxial layer of the seventh semiconductor element is higher than that of an eighth impurity concentration in the epitaxial layer of the eighth semiconductor element.

In this case, a resistance of the first semiconductor element becomes lower than a resistance of the second semiconductor element at room temperature, but a temperature rise of the first semiconductor element is greater than a temperature rise of the second semiconductor element during operation of the semiconductor device, and thus, a rising width of the resistance of the first semiconductor element becomes greater than the rising width of the resistance of the second semiconductor element. Accordingly, a difference between the resistances of the first semiconductor element and the second semiconductor element during the operation of the semiconductor device can be reduced.

In addition, at room temperature, a breakdown voltage of the first semiconductor element becomes lower than a breakdown voltage of the second semiconductor element, but the temperature rise of the first semiconductor element is greater than the temperature rise of the second semiconductor element during the operation of the semiconductor device, and thus, a rising width of the breakdown voltage of the first semiconductor element becomes greater than a rising width of the breakdown voltage of the second semiconductor element. Accordingly, it is possible to reduce variations in the breakdown voltage between the first semiconductor element and the second semiconductor element, and as a result, it is possible to reduce variations in an inductive load avalanche capability between the first semiconductor element and the second semiconductor element. Hence, variations in performance among the plurality of semiconductor elements can be reduced without increasing intervals of the semiconductor elements, that is, without increasing the size of the semiconductor device.

[8] In [7], the seventh impurity concentration may be highest among the plurality of semiconductor elements, and the eighth impurity concentration may be lowest among the plurality of semiconductor elements. In this case, the variations in the performance among the plurality of semiconductor elements can be particularly reduced.

[9] In [7] or [8], the plurality of semiconductor elements may include a ninth semiconductor element having a temperature during operation lower than that of the seventh semiconductor element and higher than that of the eighth semiconductor element, and a ninth impurity concentration in the epitaxial layer of the ninth semiconductor element may be higher than the eighth impurity concentration and lower than the seventh impurity concentration. In this case, the variations in the performance among the plurality of semiconductor elements can be particularly reduced.

[10] In any one of [7] to [9], the plurality of semiconductor elements may be arranged in a line, the seventh semiconductor element may be a semiconductor element disposed at a center, and the eighth semiconductor element may be a semiconductor element disposed at an end portion. In this case, the variations in the performance among the plurality of semiconductor elements can be particularly reduced.

[11] In any one of [1] to [10], the epitaxial layer may be formed of a wide bandgap semiconductor material. In the case of a wide bandgap semiconductor material, it is difficult to form a uniform epitaxial layer along an in-plane of the substrate, and an impurity concentration in the epitaxial layer tends to have a distribution along the in-plane of the substrate. For this reason, when the semiconductor elements are arranged at random on the conductor pattern, the variations in the performance among the plurality of semiconductor elements increase. Because the variations in the performance among the plurality of semiconductor elements is large in the case where the epitaxial layer is formed of the wide bandgap semiconductor material, a reduction range of the variations in the performance among the plurality of semiconductor elements by devising a method for arranging the plurality of semiconductor elements is wide. For this reason, the variations in the performance among the plurality of semiconductor elements can be particularly reduced.

[12] In [11], the wide bandgap semiconductor material may be silicon carbide, or gallium nitride, or gallium oxide. Silicon carbide, gallium nitride, and gallium oxide are easily available.

[13] In any one of [1] to [12], the semiconductor device may include a plurality of the insulating substrates, the conductor pattern may be formed on each insulating substrate of the plurality of insulating substrates, and the plurality of semiconductor elements may be provided on the conductor pattern. In this case, the variations in the performance among the plurality of semiconductor elements can be reduced for each conductor pattern of the plurality of conductor patterns without increasing the size of the semiconductor device.

[14] In any one of [1] to [12], the semiconductor device may include a plurality of the conductor patterns, and the plurality of semiconductor elements may be provided on the plurality of conductor patterns, respectively. In this case, the variations in the performance among the plurality of semiconductor elements can be reduced for each conductor pattern of the plurality of conductor patterns without increasing the size of the semiconductor device.

[15] In any one of [1] to [12], the semiconductor device may include a plurality of the insulating substrates, a plurality of the conductor patterns may be formed on each insulating substrate of the plurality of insulating substrates, and the plurality of semiconductor elements may be provided on the plurality of conductor patterns, respectively. In this case, the variations in the performance among the plurality of semiconductor elements can be reduced for each conductor pattern of the plurality of conductor patterns without increasing the size of the semiconductor device.

[16] In any one of [1] to [12], the semiconductor device may include a plurality of the insulating substrates, the conductor pattern may be formed on each insulating substrate of the plurality of insulating substrates, and the plurality of semiconductor elements may be provided on the conductor pattern. In this case, the variations in the performance among the plurality of semiconductor elements can be reduced for each conductor pattern of the plurality of conductor patterns without increasing the size of the semiconductor device.

[17] In any one of [1] to [16], the plurality of semiconductor elements may include a field-effect transistor. In this case, a semiconductor device including a plurality of field-effect transistors having a uniform performance can be obtained.

[18] In any one of [1] to [17], the plurality of semiconductor elements may include insulated gate bipolar transistors. In this case, a semiconductor device including a plurality of insulated gate bipolar transistors having a uniform performance can be obtained.

[19] In any one of [1] to [18], the plurality of semiconductor elements may include a Schottky barrier diode. In this case, a semiconductor device including a plurality of Schottky barrier diodes having a uniform performance can be obtained.

### DETAILS OF EMBODIMENTS OF THE PRESENT DISCLOSURE

Hereinafter, the embodiments of the present disclosure will be described in detail, but the present disclosure is not limited thereto.

### First Embodiment

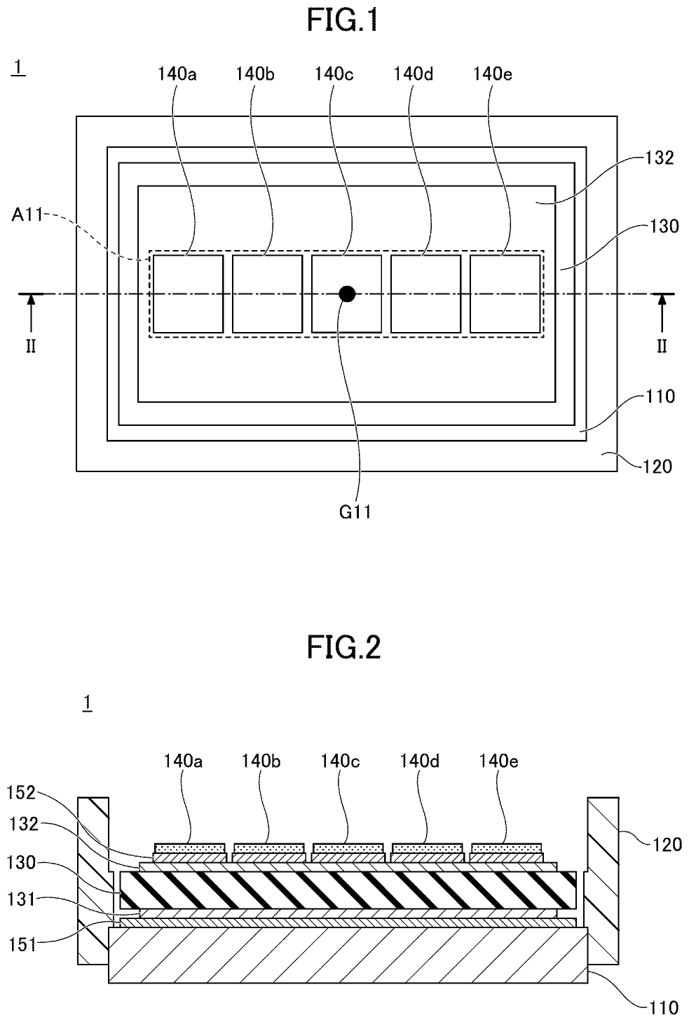

A semiconductor device 1 according to a first embodiment will be described with reference to FIG. 1 and FIG. 2. FIG. 1 is a plan view illustrating the semiconductor device 1 according to the first embodiment. FIG. 2 is a cross sectional view illustrating the semiconductor device 1 according to the first embodiment, and is the cross sectional view taken along a line II-II in FIG. 1.

The semiconductor device 1 according to the first embodiment mainly includes a heat sink 110, a housing 120, an insulating substrate 130, and a plurality of semiconductor elements 140a through 140e.

The heat sink 110 is a plate shaped body having a rectangular shape in a plan view and a uniform thickness, for example. The heat sink 110 is formed of a material having a high thermal conductivity, and may be a metal such as copper (Cu), a copper alloy, aluminum (Al), or the like, for example. The heat sink 110 is fixed to a cooler or the like using a thermal interface material (TIM) or the like.

The housing 120 is formed in a picture-frame shape in the plan view, for example, and an outer shape of the housing 120 is the same as an outer shape of the heat sink 110. The housing 120 is formed of an insulator, such as a resin or the like.

The insulating substrate 130 is disposed on the heat sink 110 inside the housing 120. The insulating substrate 130 is formed of an insulator, such as silicon nitride or the like. A conductive layer 131 is provided on a lower surface of the insulating substrate 130. The conductive layer 131 is formed of a metal, such as copper or the like. The conductive layer 131 is bonded to an upper surface of the heat sink 110 by a bonding material 151, such as solder or the like. A conductor pattern 132 is provided on an upper surface of the insulating substrate 130. The conductor pattern 132 is formed of a metal, such as copper or the like. The conductor pattern 132 has a minimum rectangular region A11 surrounding the semiconductor elements 140a through 140e in the plan view. The minimum rectangular region A11 is a region having a smallest area among rectangular regions which are present in the conductor pattern 132 and surround all of the plurality of semiconductor elements 140a through 140e in the plan view. The same applies to minimum rectangular regions A21, A22, A31, A32, A33, A34, A35, and A36, which will be described later.

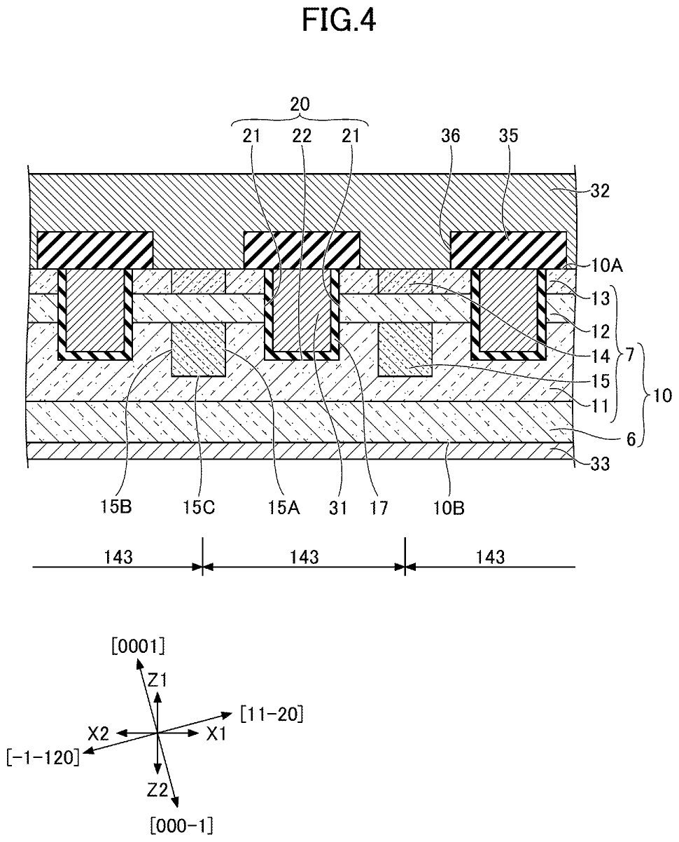

The plurality of semiconductor elements 140a through 140e are provided on the conductor pattern 132. The semiconductor elements 140a through 140e are bonded to an upper surface of the conductor pattern 132 by a bonding material 152, such as solder or the like. The plurality of semiconductor elements 140a through 140e are arranged in a line along a longitudinal direction of the conductor pattern 132. The semiconductor elements 140a and 140e are arranged at the end portions of the rectangular region A11, and the semiconductor element 140c is arranged at a center of the rectangular region A11. The plurality of semiconductor elements 140a through 140e are electrically connected in parallel. Each semiconductor device of the semiconductor elements 140a through 140e has an epitaxial layer. The epitaxial layer may be a drift region 11 (refer to FIG. 4) which will be described later. The semiconductor elements 140a through 140e are field-effect transistors (FETs). The FET is a metal-oxide-semiconductor (MOS) FET, for example.

The semiconductor elements 140a and 140e are located farthest from a center of gravity G11 of the rectangular region A11. The semiconductor element 140c is located nearest to the center of gravity G11 of the rectangular region A11. The semiconductor elements 140b and 140d are located farther from the center of gravity G11 of the rectangular region A11 than the semiconductor element 140c is from the center of gravity G11 of the rectangular region A11, and nearer to the center of gravity G11 of the rectangular region A11 than the semiconductor elements 140a and 140e are to the center of gravity G11 of the rectangular region A11. For example, a distance length between the center of gravity G11 of the rectangular region A11 and the semiconductor element 140a may be the distance between the center of gravity G11 of the rectangular region A11 and a center of gravity of the semiconductor element 140a. The same may be applied to the distances between the center of gravity G11 of the rectangular region A11 and the semiconductor elements 140b through 140e. An impurity concentration in the epitaxial layer of the semiconductor element 140c may be higher than an impurity concentration in the epitaxial layer of the semiconductor elements 140b and 140d. The impurity concentration in the epitaxial layer of the semiconductor elements 140b and 140d may be higher than the impurity concentration in the epitaxial layer of the semiconductor elements 140a and 140e. In this case, it is possible to reduce variations in performance such as a resistance, a breakdown voltage, or the like among the plurality of semiconductor elements 140a through 140e during operation of the semiconductor device 1. Detailed reasons thereof will be described later.

The semiconductor element 140a is adjacent to one semiconductor element 140b. The semiconductor element 140e is adjacent to one semiconductor element 140d. That is, the number of adjacent semiconductor elements is one for the semiconductor elements 140a and 140e. The semiconductor element 140b is adjacent to two semiconductor elements 140a and 140c. The semiconductor element 140c is adjacent to two semiconductor elements 140b and 140d. The semiconductor element 140d is adjacent to two semiconductor elements 140c and 140e. That is, the number of adjacent semiconductor elements is two for the semiconductor elements 140b through 140d. The impurity concentration in the epitaxial layer of the semiconductor elements 140b through 140d may be higher than the impurity concentration in the epitaxial layer of the semiconductor elements 140a and 140e. In this case, it is possible to reduce the variations in performance such as the resistance, the breakdown voltage, or the like among the plurality of semiconductor elements 140a through 140e during the operation of the semiconductor device 1. The detailed reason will be described later.

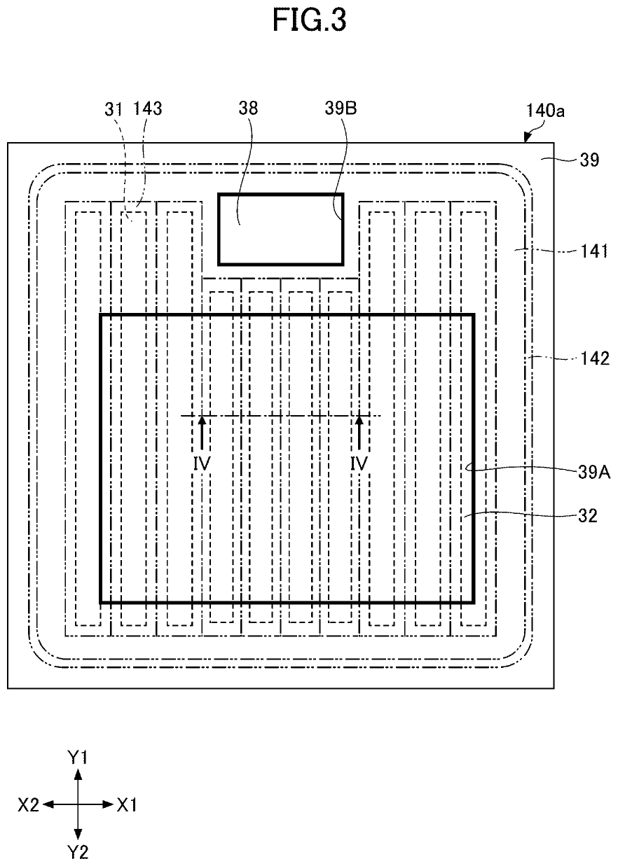

An example of the semiconductor element 140a included in the semiconductor device 1 will be described with reference to FIG. 3 and FIG. 4. FIG. 3 is a diagram illustrating a unit cell of the semiconductor element 140a. FIG. 4 is a cross sectional view illustrating the semiconductor element 140a, taken along a line IV-IV in FIG. 3. The semiconductor elements 140b through 140e may have the same configuration as the semiconductor element 140a.

The semiconductor element 140a is a transistor. The semiconductor element 140a mainly includes a silicon carbide substrate 10, a gate electrode 31, a source electrode 32, a drain electrode 33, a gate pad 38, and a passivation film 39. A first opening 39A exposing the source electrode 32 and a second opening 39B exposing the gate pad 38 are formed in the passivation film 39. The gate pad 38 is electrically connected to the gate electrode 31.

The silicon carbide substrate 10 includes a silicon carbide single crystal substrate 6 and a silicon carbide epitaxial layer 7 on the silicon carbide single crystal substrate 6. The silicon carbide substrate 10 has a principal surface 10A, and a principal surface 10A opposite to the principal surface 10B. The silicon carbide epitaxial layer 7 forms the principal surface 10A, and the silicon carbide single crystal substrate 6 forms the principal surface 10B. The silicon carbide substrate 10 has a rectangular parallelepiped shape, for example. The principal surface 10A is a surface perpendicular to the Z1-Z2 direction. <1-100> is a direction parallel to the Y1-Y2 direction. The silicon carbide single crystal substrate 6 and the silicon carbide epitaxial layer 7 are composed of hexagonal silicon carbide of polytype 4H, for example. The silicon carbide single crystal substrate 6 includes an n-type impurity, such as nitrogen (N) or the like, for example, and has an n-type conductivity. The silicon carbide epitaxial layer 7 can be formed by epitaxial growth by adding an n-type impurity such as nitrogen or the like.

The principal surface 10A is a surface in which (0001) is inclined in an off direction. For example, the off direction is [11-20]. For example, the principal surface 10A is a surface in which (0001) is inclined in the off direction ([11-20]) by an off angle of 8° or less. The off angle may be 1° or greater, or 2° or greater, for example. The off angle may be 6° or less, or 4° or less, for example.

The semiconductor element 140a includes an active region 141, and a termination region 142 provided around the active region 141.

In active region 141, the silicon carbide epitaxial layer 7 mainly has the drift region 11, a body region 12, a source region 13, a contact region 14, and an electric field relaxation region 15.

The drift region 11 includes an n-type impurity, such as nitrogen (N) or the like, for example, and has an n-type conductivity. The drift region 11 forms the principal surface 10B. The drift region 11 is an example of an epitaxial layer. The body region 12 makes contact with the drift region 11. The body region 12 includes a p-type impurity, such as aluminum (Al) or the like, for example, and has a p-type conductivity. The source region 13 is provided on the body region 12 so as to be separated from the drift region 11 by the body region 12. The source region 13 includes an n-type impurity, such as nitrogen or phosphorus (P) or the like, for example, and has an n-type conductivity. The source region 13 forms a part of the principal surface 10A. The silicon carbide epitaxial layer 7 may include a buffer layer under the drift region 11.

A plurality of gate trenches 20 are provided in the principal surface 10A. The plurality of gate trenches 20 extend parallel to the Y1-Y2 direction, and are arranged side by side in the X1-X2 direction. The gate trench 20 is defined by a side surface 21 and a bottom surface 22. The bottom surface 22 is continuous with the side surface 21. The side surface 21 penetrates the source region 13 and the body region 12. The side surface 21 reaches the drift region 11. The bottom surface 22 is located in the drift region 11. The bottom surface 22 is substantially parallel to the principal surface 10A. The side surface 21 is formed by the source region 13, the body region 12, and the drift region 11. The bottom surface 22 is formed by the drift region 11.

A gate insulating film 17, which makes contact with the side surface 21 and the bottom surface 22, is formed inside the gate trench 20. The gate insulating film 17 makes contact with the drift region 11 at the bottom surface 22. The gate insulating film 17 makes contact with the source region 13, the body region 12, and the drift region 11 at the side surface 21.

The gate electrode 31 is provided on the gate insulating film 17. The gate electrode 31 is formed of polysilicon including a conductive impurity, for example. The gate electrode 31 is disposed inside the gate trench 20. The gate electrode 31 opposes the source region 13, the body region 12, and the drift region 11. A plurality of gate electrodes 31 extend parallel to the Y1-Y2 direction, and are arranged side by side in the X1-X2 direction. The plurality of gate electrodes 31 extend along <1-100>.

The contact region 14 is provided between the gate trenches 20 that are adjacent to each other in the X1-X2 direction, so that the contact region 14 is separated from the side surface 21 of each gate trench 20, penetrates the source region 13, and makes contact with the body region 12. The contact region 14 forms a part of the principal surface 10A. The contact region 14 includes a p-type impurity, such as aluminum or the like, for example, and has a p-type conductivity.

The electric field relaxation region 15 is provided between the gate trenches 20 that are adjacent to each other in the X1-X2 direction, so as to extend from the body region 12 toward the principal surface 10B and separated from the side surface 21 of each gate trench 20. The electric field relaxation region 15 includes a p-type impurity, such as aluminum or the like, for example, and has a p-type conductivity. The electric field relaxation region 15 has a lower end surface 15C, a first side end surface 15A, and a second side end surface 15B. The lower end surface 15C is substantially parallel to the XY plane. The first side end surface 15A and the second side end surface 15B are substantially parallel to the YZ plane. The first side end surface 15A is located on the X1-side of the second side end surface 15B. The lower end surface 15C, the first side end surface 15A, and the second side end surface 15B are make contact with the drift region 11.

An interlayer insulating film 35 is provided so as to cover the gate trenches 20 and the gate electrodes 31. A contact hole 36 is formed in the interlayer insulating film 35 so as to expose a portion of the source region 13 and the contact region 14.

The source electrode 32 is provided on the interlayer insulating film 35 and makes contact with the principal surface 10A through the contact hole 36. The source electrode 32 is electrically connected to the source region 13 and the contact region 14. The interlayer insulating film 35 electrically insulates the gate electrode 31 and the source electrode 32 from each other.

The drain electrode 33 makes contact with the principal surface 10B. The drain electrode 33 is electrically connected to the drift region 11.

The semiconductor element 140a includes a plurality of unit cells 143, in units of periodic patterns of the gate trenches 20, inside the active region 141. The plurality of unit cells 143 are arranged in the X1-X2 direction, with a longitudinal direction thereof extending in the Y1-Y2 direction. The plurality of unit cells 143 extend along <1-100>.

The termination region 142 is a region having an annular planar shape, for example, and forms a part of the principal surface 10A. The termination region 142 includes a p-type impurity, such as aluminum or the like, for example, and has a p-type conductivity.

Next, the reason why the variations in the performance, such as the resistance, the breakdown voltage, or the like among the plurality of semiconductor elements 140a through 140e during the operation of the semiconductor device 1 can be reduced will be described with reference to FIG. 5 through FIG. 7.

In the semiconductor device, the temperature of the semiconductor element rises during the operation. In the semiconductor device 1 according to the first embodiment, the nearer a location is to the center of gravity G11 of the rectangular region A11, the more heat is accumulated during the operation. For this reason, the temperature of the semiconductor element 140c located nearest to the center of gravity G11 of the rectangular region A11 is more likely to rise more than the temperatures of the semiconductor elements 140a and 140e located farthest from the center of gravity G11 of the rectangular region A11. In addition, during the operation of the semiconductor device 1, the larger the number of adjacent semiconductor elements, the more the semiconductor device 1 is affected by the heat generated from the adjacent semiconductor elements. For this reason, the temperatures of the semiconductor elements 140b through 140d having the largest number of adjacent semiconductor elements is more likely to rise than the temperatures of the semiconductor elements 140a and 140e having the smallest number of adjacent semiconductor elements.

The resistance of the semiconductor element decreases as the impurity concentration in the epitaxial layer of the semiconductor device increases. Hence, the impurity concentration in the epitaxial layer of the semiconductor element 140c disposed at a position where the temperature during the operation is the highest is set higher than the impurity concentration in the epitaxial layer of the semiconductor elements 140a and 140e disposed at positions where the temperature during the operation is the lowest. In this case, because the temperature of the semiconductor element 140c rises more than the temperature of the semiconductor elements 140a and 140e during the operation of the semiconductor device 1, the amount of increase in the resistance of the semiconductor element 140c becomes larger than the amount of increase in the resistance of the semiconductor elements 140a and 140e. Accordingly, a difference between the resistance the semiconductor element 140c and the resistance of the semiconductor elements 140a and 140e during the operation of the semiconductor device 1 becomes small. In addition, at room temperature, the breakdown voltage of the semiconductor element 140c is lower than the breakdown voltage of the semiconductor elements 140a and 140e, but because the temperature of the semiconductor element 140c rises more than the temperature of the semiconductor elements 140a and 140e during the operation of the semiconductor device, a rising width of the breakdown voltage of the semiconductor element 140c becomes larger than a rising width of the breakdown voltage of the semiconductor elements 140a and 140e. For this reason, the variations in the breakdown voltage between the semiconductor element 140c and the semiconductor elements 140a and 140e can be reduced, and as a result, the variations in an inductive load avalanche capability between the semiconductor element 140c and the semiconductor elements 140a and 140e can be reduced. Accordingly, the variations in the performance among the plurality of semiconductor elements 140a through 140e can be reduced, without increasing the intervals of the semiconductor elements 140a through 140e, that is, without increasing the size of the semiconductor device 1.

FIG. 5 is a diagram illustrating a relationship between the temperature and resistance of a transistor, which is an example of the semiconductor element. In FIG. 5, the abscissa indicates the temperature of the semiconductor device, and the ordinate indicates the resistance of the semiconductor element. In FIG. 5, a solid line indicates the resistance of a first semiconductor element, that is disposed at a position where the temperature is likely to rise during the operation of the semiconductor device, and has the epitaxial layer having a first impurity concentration. In FIG. 5, a broken line indicates the resistance of a second semiconductor element, that is disposed at a position where the temperature is unlikely to rise during the operation of the semiconductor device, and has the epitaxial layer having a second impurity concentration lower than the first impurity concentration.

As illustrated in FIG. 5, in a case where the semiconductor device is in an initial stage of the operation and the temperature at a predetermined position of the semiconductor device is 25° C., the first semiconductor element exhibits a resistance lower than a resistance of the second semiconductor element. This is because, in the case where the semiconductor device is in the initial stage of the operation, the temperatures of the first semiconductor element and the second semiconductor element are the same, and the first impurity concentration in the epitaxial layer of the first semiconductor element is higher than the second impurity concentration in the epitaxial layer of the second semiconductor element. In contrast, in a case where the temperature at the predetermined position of the semiconductor device becomes 175° C. in accordance with the operation of the semiconductor device, the difference between the resistance of the first semiconductor element and the resistance of the second semiconductor element becomes small. This is because a rising width of the resistance of the first semiconductor element when the temperature at the predetermined position of the semiconductor device increases from 25° C. to 175° C. in accordance with the operation of the semiconductor device is larger than a rising width of the resistance of the second semiconductor element. The temperature at the predetermined position may be the temperature of the first semiconductor element, or the temperature of the second semiconductor element, or a temperature of another position in the semiconductor device, for example.

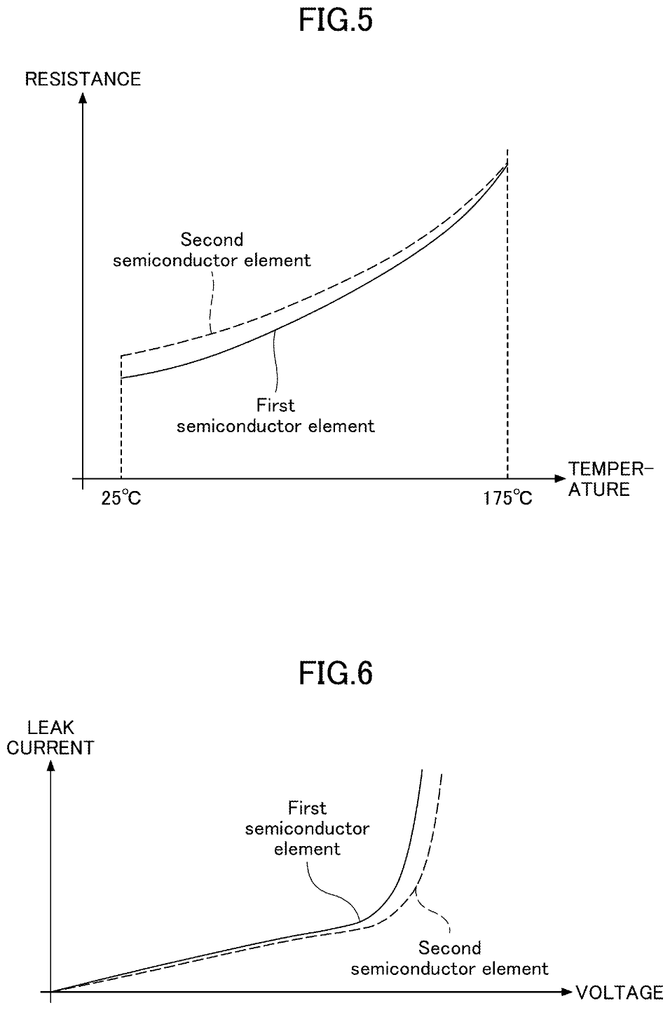

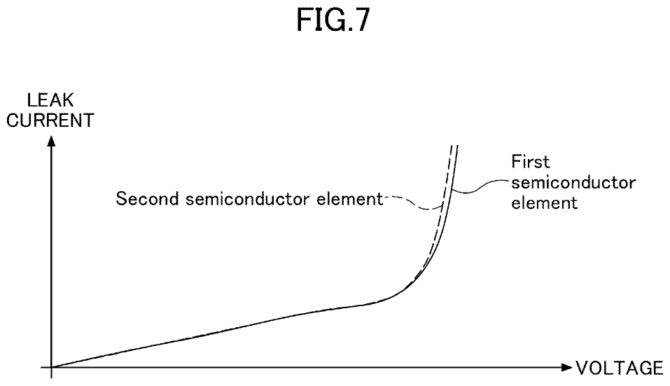

FIG. 6 and FIG. 7 are diagrams illustrating breakdown characteristics of the transistor, which is an example of semiconductor element. FIG. 6 illustrates the breakdown characteristics of the transistor for a case where the temperature at the predetermined position of the semiconductor device is 25° C., and FIG. 7 illustrates the breakdown characteristics of the transistor for a case where the temperature at the predetermined position of the semiconductor device is 175° C. In FIG. 6 and FIG. 7, the abscissa indicates a reverse voltage, and the ordinate indicates a reverse current.

As illustrated in FIG. 6, in the case where the temperature at the predetermined position of the semiconductor device is 25° C., a difference is generated between breakdown voltages of the first semiconductor element and the second semiconductor element. This is because a carrier concentration in the first semiconductor element is higher than a carrier concentration in the second semiconductor element, thereby making the breakdown voltage of the first semiconductor element lower than the breakdown voltage of the second semiconductor element. In contrast, as illustrated in FIG. 7, in the case where the temperature at the predetermined position of the semiconductor device is 175° C., the difference between the breakdown voltages of the first semiconductor element and the second semiconductor element is small.

### Second Embodiment

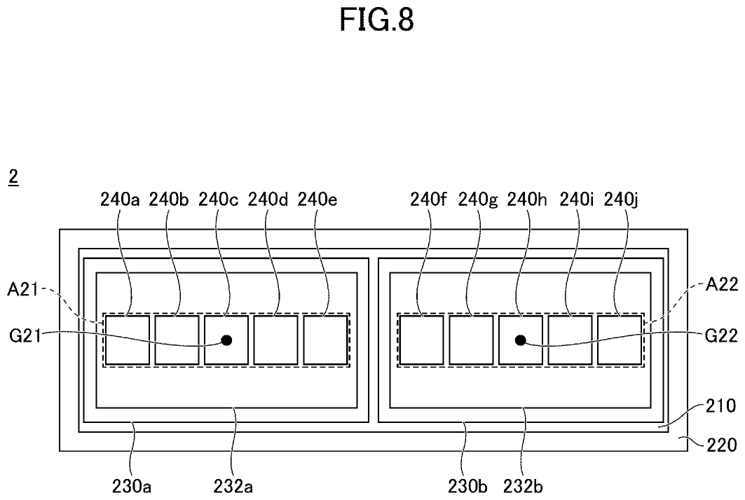

A semiconductor device 2 according to a second embodiment will be described with reference to FIG. 8. FIG. 8 is a plan view illustrating the semiconductor device 2 according to the second embodiment.

The semiconductor device 2 according to the second embodiment mainly includes a heat sink 210, a housing 220, two insulating substrates 230a and 230b, and a plurality of semiconductor elements 240a through 240j. Configurations of the heat sink 210 and the housing 220 are the same as the configurations of the heat sink 110 and the housing 120, respectively.

The two insulating substrates 230a and 230b are disposed on the same heat sink 210 inside the housing 220. The insulating substrates 230a and 230b are arranged side by side with a space therebetween in the plan view. A conductive layer (not illustrated) is provided on a lower surface of each of the insulating substrates 230a and 230b. The conductive layer is bonded to an upper surface of the heat sink 210 by a bonding material (not illustrated), such as solder or the like, similar to the conductive layer 131. A conductor pattern 232a is provided on an upper surface of the insulating substrate 230a. The conductor pattern 232a has a minimum rectangular region A21 surrounding the semiconductor elements 240a through 240e in the plan view. A conductor pattern 232b is provided on an upper surface of the insulating substrate 230b. The conductor pattern 232b has a minimum rectangular region A22 surrounding the semiconductor elements 240f through 240j in the plan view. The conductor patterns 232a and 232b are formed of a metal, such as copper or the like.

The plurality of semiconductor elements 240a through 240e are provided on the conductor pattern 232a. The plurality of semiconductor elements 240a through 240e are bonded to an upper surface of the conductor pattern 232a by a bonding material (not illustrated), such as solder or the like. The plurality of semiconductor elements 240a through 240e are arranged in a line along a longitudinal direction of the conductor pattern 232a. The semiconductor elements 240a and 240e are arranged at the end portions of the rectangular region A21, and the semiconductor element 240c is arranged at the center of the rectangular region A21. The plurality of semiconductor elements 240a through 240e are electrically connected in parallel. A configuration of each of the semiconductor elements 240a through 240e is the same as the configuration of each of the semiconductor elements 140a through 140e.

The semiconductor elements 240a and 240e are located farthest from a center of gravity G21 of the rectangular region A21. The semiconductor element 240c is located nearest to the center of gravity G21 of the rectangular region A21. The semiconductor elements 240b and 240d are located farther from the center of gravity G21 of the rectangular region A21 than the semiconductor elements 240c is from the center of gravity G21 of the rectangular region A21, and nearer to the center of gravity G21 of the rectangular region A21 than the semiconductor elements 240a and 240e are to the center of gravity G21 of the rectangular region A21. For example, a distance between the center of gravity G21 of the rectangular region A21 and the semiconductor element 240a may be the distance between the center of gravity G21 of the rectangular region A21 and a center of gravity of the semiconductor element 240a. The same may be applied to the distances between the center of gravity G21 of the rectangular region A21 and the semiconductor elements 240b through 240e. An impurity concentration in the epitaxial layer of the semiconductor element 240c may be higher than an impurity concentration in the epitaxial layer of the semiconductor elements 240b and 240d. The impurity concentration in the epitaxial layer of the semiconductor elements 240b and 240d may be higher than the impurity concentration in the epitaxial layer of the semiconductor elements 240a and 240e. In this case, similar to the first embodiment, it is possible to reduce variations in the performance, such as the resistance, the breakdown voltage, or the like among the plurality of semiconductor elements 240a through 240e during the operation of the semiconductor device 2.

The semiconductor element 240a is adjacent to one semiconductor element 240b on the conductor pattern 232a. The semiconductor element 240e is adjacent to one semiconductor element 240d on the conductor pattern 232a. That is, the number of adjacent semiconductor elements on the conductor pattern 232a is one for the semiconductor elements 240a and 240e. The semiconductor element 240b is adjacent to two semiconductor elements 240a and 240c on the conductor pattern 232a. The semiconductor element 240c is adjacent to two semiconductor elements 240b and 240d on the conductor pattern 232a. The semiconductor element 240d is adjacent to two semiconductor elements 240c and 240e on the conductor pattern 232a. That is, the number of adjacent semiconductor elements provided on the conductor pattern 232a is two for the semiconductor elements 240b through 240d. An impurity concentration in the epitaxial layer of the semiconductor elements 240b through 240d may be higher than an impurity concentration in the epitaxial layer of the semiconductor elements 240a and 240e. In this case, similar to the first embodiment, it is possible to reduce variations in the performance, such as the resistance, the breakdown voltage, or the like among the plurality of semiconductor elements 240a through 240e during the operation of the semiconductor device 2.

The semiconductor elements 240f through 240j are provided on the conductor pattern 232b. The semiconductor elements 240f through 240j are bonded to an upper surface of the conductor pattern 232b by a bonding material (not illustrated), such as solder or the like. The plurality of semiconductor elements 240f through 240j are arranged in a line along a longitudinal direction of the conductor pattern 232b. The semiconductor elements 240a and 240e are arranged at end portions of the rectangular region A22, and the semiconductor element 240c is arranged at a center of the rectangular region A22. The plurality of semiconductor elements 240f through 240j are electrically connected in parallel. A configuration of each of the semiconductor elements 240f through 240j is the same as the configuration of each of the semiconductor elements 240a through 240e.

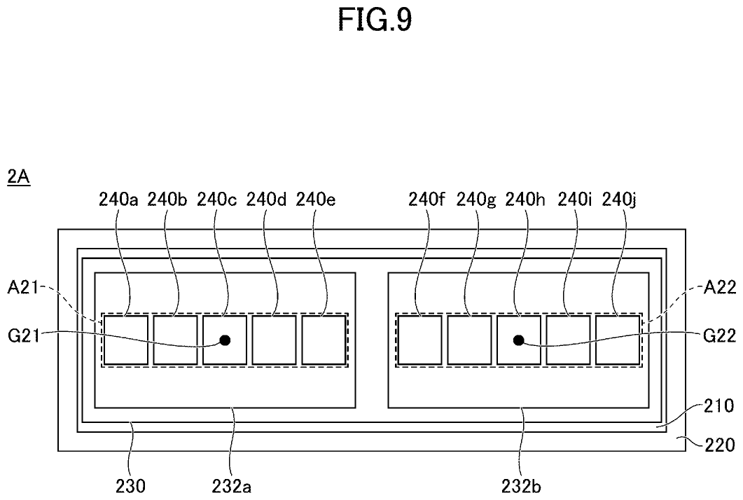

A semiconductor device 2A according to a modification of the second embodiment will be described with reference to FIG. 9. FIG. 9 is a plan view illustrating the semiconductor device 2A according to the modification of the second embodiment.

As illustrated in FIG. 9, in the semiconductor device 2A according to the modification of the second embodiment, one insulating substrate 230 is disposed on the heat sink 210. The conductor patterns 232a and 232b are provided on the upper surface of the insulating substrate 230. The conductor patterns 232a and 232b are arranged side by side with a space therebetween in the plan view. Other configurations are the same as those of the second embodiment.

According to such a modification, it is possible to obtain the same effects as those obtainable by the second embodiment.

### Third Embodiment

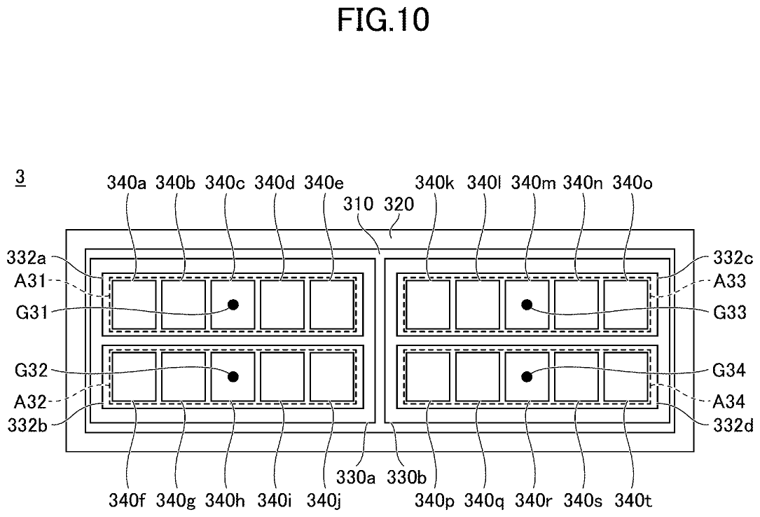

A semiconductor device 3 according to a third embodiment will be described with reference to FIG. 10. FIG. 10 is a plan view illustrating a semiconductor device 3 according to the third embodiment.

The semiconductor device 3 according to the third embodiment mainly includes a heat sink 310, a housing 320, two insulating substrates 330a and 330b, and a plurality of semiconductor elements 340a through 340t. Configurations of the heat sink 310 and the housing 320 are the same as the configurations of the heat sink 110 and the housing 120, respectively.

The two insulating substrates 330a and 330b are disposed on the same heat sink 310 inside the housing 320. The insulating substrates 330a and 330b are arranged side by side with a space therebetween in the plan view. A conductive layer (not illustrated) is provided on a lower surface of each of the insulating substrates 330a and 330b. The conductive layer is bonded to an upper surface of the heat sink 310 by a bonding material (not illustrated), such as solder or the like, similar to the conductive layer 131.

Conductor patterns 332a and 332b are provided on the upper surface of the insulating substrate 330a. The conductor pattern 332a has a minimum rectangular region A31 surrounding the semiconductor elements 340a through 340e in the plan view. The conductor pattern 332b has a minimum rectangular region A32 surrounding the semiconductor elements 340f through 340j in the plan view.

Conductor patterns 332c and 332d are provided on the upper surface of the insulating substrate 330b. The conductor pattern 332c has a minimum rectangular region A33 surrounding the semiconductor elements 340k through 340o in the plan view. The conductor pattern 332d has a minimum rectangular region A34 surrounding the semiconductor elements 340p through 340t in the plan view.

The conductor patterns 332a through semiconductor element 332d are formed of a metal, such as copper or the like.

The semiconductor elements 340a through 340e are provided on the conductor pattern 332a. The semiconductor elements 340a through 340e are bonded to an upper surface of the conductor pattern 332a by a bonding material (not illustrated), such as solder or the like. The plurality of semiconductor elements 340a through 340e are arranged in a line along a longitudinal direction of the conductor pattern 332a. The semiconductor elements 340a and 340e are arranged at end portions of the rectangular region A31, and the semiconductor element 340c is arranged at a center of the rectangular region A31. The plurality of semiconductor elements 340a through 340e are electrically connected in parallel. A configuration of each of the semiconductor elements 340a through 340e is the same as the configuration of each of the semiconductor elements 140a through 140e.

The semiconductor elements 340a and 340e are located farthest from the center of gravity G31 of the rectangular region A31. The semiconductor element 340c is located nearest to the center of gravity G31 of the rectangular region A31. The semiconductor elements 340b and 340d are located farther from the center of gravity G31 of the rectangular region A31 than the semiconductor element 340c is from the center of gravity G31 of the rectangular region A31 and nearer to the center of gravity G31 of the rectangular region A31 than the semiconductor elements 340a and 340e are to the center of gravity G31 of the rectangular region A31. For example, a distance between the center of gravity G31 of the rectangular region A31 and the semiconductor element 340a may be the distance between the center of gravity G31 of the rectangular region A31 and a center of gravity of the semiconductor element 340a. The same may be applied to the distances between the center of gravity G31 of the rectangular region A31 and the semiconductor elements 340b through 340e. An impurity concentration in the epitaxial layer of the semiconductor element 340c may be higher than an impurity concentration in the epitaxial layer of the semiconductor elements 340b and 340d. The impurity concentration in the epitaxial layer of the semiconductor elements 340b and 340d may be higher than the impurity concentration in the epitaxial layer of the semiconductor elements 340a and 340e. In this case, similar to the first embodiment, it is possible to reduce variations in the performance, such as the resistance, the breakdown voltage, or the like among the plurality of semiconductor elements 340a through 340e during operation of the semiconductor device 3.

The semiconductor element 340a is adjacent to one semiconductor device 340b on the conductor pattern 332a. The semiconductor element 340e is adjacent to one semiconductor device 340d on the conductor pattern 332a. That is, the number of adjacent semiconductor elements provided on the conductor pattern 332a is one for the semiconductor elements 340a and 340e. The semiconductor element 340b is adjacent to two semiconductor elements 340a and 340c on the conductor pattern 332a. The semiconductor element 340c is adjacent to two semiconductor elements 340b and 340d on the conductor pattern 332a. The semiconductor element 340d is adjacent to two semiconductor elements 340c and 340e on the conductor pattern 332a. That is, the number of adjacent semiconductor elements provided on the conductor pattern 332a is two for the semiconductor elements 340b through 340d. An impurity concentration in the epitaxial layer of the semiconductor elements 340b through 340d may be higher than an impurity concentration in the epitaxial layer of the semiconductor elements 340a and 340e. In this case, similar to the first embodiment, it is possible to reduce variations in the performance, such as the resistance, the breakdown voltage, or the like among the plurality of semiconductor elements 340a through 340e during operation of the semiconductor device 3.

The semiconductor elements 340f through 340j are provided on the conductor pattern 332b. The semiconductor elements 340f through 340j are bonded to an upper surface of the conductor pattern 332b by a bonding material (not illustrated), such as solder or the like. The plurality of semiconductor elements 340f through 340j are arranged in a line along a longitudinal direction of the conductor pattern 332b. The semiconductor elements 340f and 340j are arranged at end portions of the rectangular region A32, and the semiconductor element 340h is arranged at a center of the rectangular region A32. The plurality of semiconductor elements 340f through 340j are electrically connected in parallel. A configuration of each of the semiconductor elements 340f through 340j is the same as the configuration of each of the semiconductor elements 340a through 340e.

The semiconductor elements 340k through 340c are provided on the conductor pattern 332c. The semiconductor elements 340k through 340o are bonded to an upper surface of the conductor pattern 332c by a bonding material (not illustrated), such as solder or the like. The plurality of semiconductor elements 340k through 340o are arranged in a line along a longitudinal direction of the conductor pattern 332c. The semiconductor elements 340k and 340o are arranged at end portions of the rectangular region A33, and the semiconductor element 340m is arranged at a center of the rectangular region A33. The plurality of semiconductor elements 340k through 340o are electrically connected in parallel. A configuration of each of the semiconductor elements 340k through 340o is the same as the configuration of each of the semiconductor elements 340a through 340e.

The semiconductor elements 340p through 340t are provided on the conductor pattern 332d. The semiconductor elements 340p through 340t are bonded to an upper surface of the conductor pattern 332d by a bonding material (not illustrated), such as solder or the like. The plurality of semiconductor elements 340p through 340t are arranged in a line along a longitudinal direction of the conductor pattern 332d. The semiconductor elements 340p and 340t are arranged at end portions of the rectangular region A34, and the semiconductor element 340r is arranged at a center of the rectangular region A34. The plurality of semiconductor elements 340p through 340t are electrically connected in parallel. A configuration of each of the semiconductor elements 340p through 340t is the same as the configuration of each of the semiconductor elements 340a through 340e.

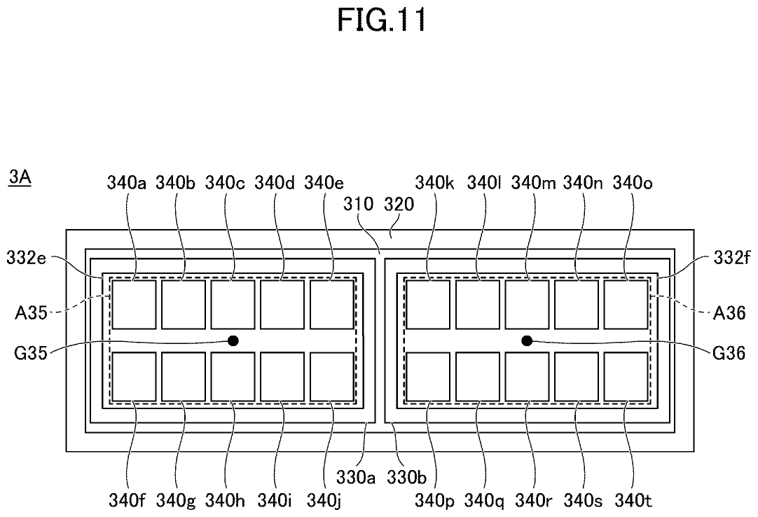

A semiconductor device 3A according to a modification of the third embodiment will be described with reference to FIG. 11. FIG. 11 is a plan view illustrating the semiconductor device 3A according to the modification of the third embodiment.

As illustrated in FIG. 11, in the semiconductor device 3A according to the modification of the third embodiment, one conductor pattern 332e is disposed on an insulating substrate 330a, and one conductor pattern 332f is disposed on an insulating substrate 330b. The conductor pattern 332e has a minimum rectangular region A35 surrounding the semiconductor elements 340a through 340j in the plan view. The conductor pattern 332f has a minimum rectangular region A36 surrounding the semiconductor elements 340k through 340t in the plan view. The rectangular regions A35 and A36 have centers of gravity G35 and G36, respectively. The plurality of semiconductor elements 340a through 340j are provided on the conductor pattern 332e. The plurality of semiconductor elements 340k through 340t are provided on the conductor pattern 332f. Other configurations are the same as those of the third embodiment.

According to such a modification, it is possible to obtain the same effects as those obtainable by the third embodiment.

Although the embodiments are described above in detail, the present invention is not limited to the specific embodiments, and various variations and modifications can be made within the scope described in the claims.

In the embodiments described above, the case where the epitaxial layer is formed of silicon carbide is described, but the present disclosure is not limited thereto. For example, the epitaxial layer is preferably formed of a wide bandgap semiconductor material. Examples of the wide bandgap semiconductor material, other than silicon carbide, include gallium nitride, gallium oxide, or the like. In the case of the wide bandgap semiconductor material, it is difficult to form a uniform epitaxial layer, and the impurity concentration in the epitaxial layer tends to have a distribution along an in-plane of the substrate. For this reason, when the semiconductor elements are arranged at random on the conductor pattern, the variations in the performance among the plurality of semiconductor elements increase. Because the variations in the performance among the plurality of semiconductor elements is large in the case where the epitaxial layer is formed of the wide bandgap semiconductor material, a reduction range of the variations in the performance among the plurality of semiconductor elements by devising a method for arranging the plurality of semiconductor elements is wide. For this reason, the variations in the performance among the plurality of semiconductor elements can be particularly reduced.

In the embodiments described above, the case where the plurality of semiconductor elements are MOSETs is described, but the present disclosure is not limited thereto. For example, the plurality of semiconductor elements may include at least a MOSFET or at least an insulated gate bipolar transistor (IGBT), or at least a Schottky barrier diode (SBD). In this case, a semiconductor device including at least a plurality of MOSFETs having the same performance, or at least a plurality of IGBTs having the same performance, or at least a plurality of SBDs having the same performance can be obtained.

In the embodiments described above, the n-type is described as the first conductivity type and the p-type is described as the second conductivity type, but the p-type may be the first conductivity type and the n-type may be the second conductivity type.

### DESCRIPTION OF REFERENCE NUMERALS

1: Semiconductor device
6: Silicon carbide single crystal substrate
7: Silicon carbide epitaxial layer
10: Silicon carbide substrate
10A: Principal surface
10B: Principal surface
11: Drift region (epitaxial layer)
12: Body region
13: Source region
14: Contact region
15: Electric field relaxation region
15A: First side end surface
15B: Second side end surface
15C: Lower end surface
17: Gate insulating film
20: Gate trench
21: Side surface
22: Bottom surface
31: Gate electrode
32: Source electrode
33: Drain electrode
35: Interlayer insulator film
36: Contact hole
38: Gate pad
39: Passivation film
39A: First opening
39B: Second opening
110: Heat sink
120: Housing
130: Insulating substrate
131: Conductive layer
132: Conductor pattern
140a, 140b, 140c, 140d, 140e: Semiconductor element
141: Active region
142: Termination region
143: Unit cell
151, 152: Bonding material
2, 2A: Semiconductor device
210: Heat sink
220: Housing
230, 230a, 230b: Insulating substrate
232a, 232b: Conductor pattern
240a, 240b, 240c, 240d, 240e, 240f, 240g, 240h, 240i, 240j: Semiconductor element
3, 3A Semiconductor device
310: Heat sink
320: Housing
330a, 330b: Insulating substrate
332a, 332b, 332c, 332d, 332e, 332f: Conductor pattern
340a, 340b, 340c, 340d, 340e, 340f, 340g, 340h, 340i, 340j, 340k, 3401, 340m, 340n, 340o, 340p, 340q, 340r, 340s, 340t: Semiconductor element
A11, A21, A22, A31, A32, A33, A34, A35, A36: Rectangular region
G11, G21, G22, G31, G32, G33, G34, G35, G36: Center of gravity

1. A semiconductor device comprising:
an insulating substrate;
a conductor pattern formed on the insulating substrate; and
a plurality of semiconductor elements provided on the conductor pattern and electrically connected in parallel, wherein
the conductor pattern has a minimum rectangular region surrounding the plurality of semiconductor elements in a plan view,
each semiconductor element of the plurality of semiconductor elements has an epitaxial layer of a first conductivity type,
the plurality of semiconductor elements include:
a first semiconductor element located nearest to a center of gravity of the rectangular region; and
a second semiconductor element located farthest from the center of gravity of the rectangular region, and
a first impurity concentration in the epitaxial layer of the first semiconductor element is higher than a second impurity concentration in the epitaxial layer of the second semiconductor element.

2. The semiconductor device as claimed in claim 1, wherein
the first impurity concentration is highest among the plurality of semiconductor elements, and
the second impurity concentration is lowest among the plurality of semiconductor elements.

3. The semiconductor device as claimed in claim 1, wherein
the plurality of semiconductor elements include a third semiconductor element that is farther from the center of gravity of the rectangular region than the first semiconductor element is from the center of gravity of the rectangular region and nearer to the center of gravity of the rectangular region than the second semiconductor element is to the center of gravity of the rectangular region, and
a third impurity concentration in the epitaxial layer of the third semiconductor element is higher than the second impurity concentration and lower than the first impurity concentration.

4. A semiconductor device comprising:
an insulating substrate;
a conductor pattern formed on the insulating substrate; and
a plurality of semiconductor elements provided on the conductor pattern and electrically connected in parallel, wherein
each semiconductor element of the plurality of semiconductor elements has an epitaxial layer of a first conductivity type,
the plurality of semiconductor elements include:
a fourth semiconductor element having a largest number of semiconductor elements adjacent to each other; and
a fifth semiconductor element having a smallest number of semiconductor elements adjacent to each other, and
a fourth impurity concentration in the epitaxial layer of the fourth semiconductor element is higher than a fifth impurity concentration in the epitaxial layer of the fifth semiconductor element.

5. The semiconductor device as claimed in claim 4, wherein
the fourth impurity concentration is highest among the plurality of semiconductor elements, and
the fifth impurity concentration is lowest among the plurality of semiconductor elements.

6. The semiconductor device as claimed in claim 4, wherein
the plurality of semiconductor elements include a sixth semiconductor element having a number of adjacent semiconductor elements smaller than that of the fourth semiconductor element and larger than that of the fifth semiconductor element, and
a sixth impurity concentration in the epitaxial layer of the sixth semiconductor element is higher than the fifth impurity concentration and lower than the fourth impurity concentration.

7. A semiconductor device comprising:
an insulating substrate;
a conductor pattern formed on the insulating substrate; and
a plurality of semiconductor elements provided on the conductor pattern and electrically connected in parallel, wherein
each semiconductor element of the plurality of semiconductor elements has an epitaxial layer of a first conductivity type,
the plurality of semiconductor elements include:
a seventh semiconductor element having a highest temperature during operation; and
an eighth semiconductor element having a lowest temperature during operation, and
a seventh impurity concentration in the epitaxial layer of the seventh semiconductor element is higher than that of an eighth impurity concentration in the epitaxial layer of the eighth semiconductor element.

8. The semiconductor device as claimed in claim 7, wherein
the seventh impurity concentration is highest among the plurality of semiconductor elements, and
the eighth impurity concentration is lowest among the plurality of semiconductor elements.

9. The semiconductor device as claimed in claim 7, wherein
the plurality of semiconductor elements include a ninth semiconductor element having a temperature during operation lower than that of the seventh semiconductor element and higher than that of the eighth semiconductor element, and
a ninth impurity concentration in the epitaxial layer of the ninth semiconductor element is higher than the eighth impurity concentration and lower than the seventh impurity concentration.

10. The semiconductor device as claimed in claim 7, wherein
the plurality of semiconductor elements are arranged in a line,
the seventh semiconductor element is a semiconductor element disposed at a center, and
the eighth semiconductor element is a semiconductor element disposed at an end portion.

11. The semiconductor device as claimed in claim 1, wherein
the epitaxial layer is formed of a wide bandgap semiconductor material.

12. The semiconductor device as claimed in claim 11, wherein
the wide bandgap semiconductor material is silicon carbide, or gallium nitride, or gallium oxide.

13. The semiconductor device as claimed in claim 1, comprising:
a plurality of the insulating substrates, wherein
the conductor pattern is formed on each insulating substrate of the plurality of insulating substrates, and
the plurality of semiconductor elements are provided on the conductor pattern.

14. The semiconductor device as claimed in claim 1, comprising:
a plurality of the conductor patterns,
wherein the plurality of semiconductor elements are provided on the plurality of conductor patterns, respectively.

15. The semiconductor device as claimed in claim 1, comprising:
a plurality of the insulating substrates, wherein
a plurality of the conductor patterns are formed on each insulating substrate of the plurality of insulating substrates, and
the plurality of semiconductor elements are provided on the plurality of conductor patterns, respectively.

16. The semiconductor device as claimed in claim 1, comprising:
a plurality of the insulating substrates, wherein
the conductor pattern is formed on each insulating substrate of the plurality of insulating substrates, and
the plurality of semiconductor elements are provided on the conductor pattern.

17. The semiconductor device as claimed in claim 1, wherein
the plurality of semiconductor elements include a field effect transistor.

18. The semiconductor device as claimed in claim 1, wherein
the plurality of semiconductor elements include an insulated gate bipolar transistor.

19. The semiconductor device as claimed in claim 1, wherein
the plurality of semiconductor elements include a Schottky barrier diode.
